(19) United States
(12) Patent Application Publication
(10) Pub. No.: US 2025/0126754 A1
(43) Pub. Date: Apr. 17, 2025

(54) SEMI-SOLID ALLOY THERMAL INTERFACE COMPOSITION AND METHOD FOR DISSIPATING HEAT FROM AN ELECTRONIC COMPONENT USING THE SAME

(71) Applicant: NATIONAL CHENG KUNG UNIVERSITY, Tainan City (TW)

(72) Inventors: Shih-kang LIN, Tainan City (TW); Chih-yao HUANG, Tainan City (TW); Chih-han YANG, Tainan City (TW)

(21) Appl. No.: 18/913,190

(22) Filed: Oct. 11, 2024

Related U.S. Application Data
(60) Provisional application No. 63/544,191, filed on Oct. 15, 2023.

(51) Int. Cl. H05K 7/20; C22C 13/02; C22C 28/00; C22C 30/02; C22C 30/04

(52) U.S. Cl. CPC H05K 7/2039; C22C 13/02; C22C 28/00; C22C 30/02; C22C 30/04

(57) ABSTRACT

A semi-solid alloy thermal interface composition and method for dissipating heat from an electronic component using the same are disclosed in the present disclosure. The semi-solid alloy thermal interface material comprises, based on total atoms of 100 at. %, 0.1-10 at. % of Bi, 20-30 at. % of In, and 65-75 at. % of Sn. In a method for dissipating heat from an electronic component using the semi-solid alloy thermal interface material, the semi-solid alloy thermal interface material is disposed between a chip and a heat sink, wherein the semi-solid alloy thermal interface material is completely solid at a room-temperature, and has a liquid content ranging from 0.1 to 70 mol % based on a total mole of 100 mol % of the semi-solid alloy thermal interface composition at a temperature of 40 to 130° C.

### CROSS-REFERENCE TO RELATED APPLICATIONS

This application claims the benefit of U.S. Provisional Application No. 63/544,191, filed on Oct. 15, 2023, which is hereby incorporated by reference in its entirety herein.

### FIELD OF INVENTION

The present disclosure relates to a heat dissipation composition, and in particular to a semi-solid alloy thermal interface composition.

### BACKGROUND OF INVENTION

When electronic components operate, heat is generated. If an operating temperature exceeds a temperature that the electronic components can withstand, it may cause damage to the electronic components. A heat sink is a widely used method of heat dissipation which can dissipate heat generated by the electronic components. In order to further improve heat dissipation efficiency, thermal interface material (TIM) is further used between the electronic component and the heat sink to fill holes caused by bonding or contact between the electronic component and the heat sink, thereby reducing thermal contact resistance between the heat sink and the electronic component.

Thermal interface materials comprise solid, liquid, and composite forms. Solid thermal interface materials, for example, comprise tapes and silicone sheets, and liquid thermal interface materials, for example, comprise such as gel and thermal paste. However, the liquid thermal interface materials are prone to flow during operation of the electronic components, and have limitations of installation and usage. The solid thermal interface materials require reflow technologies, and brittle compounds are easily formed on interfaces, thereby reducing thermal and mechanical properties. Composite thermal interface materials have disadvantages of complex preparations and involving unstable materials, so that chemical reactions are prone to occur during use. In addition, it is difficult to evaluate material properties and reliability of the composite thermal interface materials.

In summary, the conventional thermal interface materials need to be improved.

### SUMMARY OF INVENTION

### Technical Problems

A main purpose of the present disclosure is to provide a semi-solid alloy thermal interface composition to solve the above technical problems, including instability of the liquid thermal interface materials installed on the electronics, inconvenience for the solid thermal interface materials to install on the electronic components, poor thermal conductivities and mechanical properties of the solid thermal interface materials, and complicated preparations and unstable properties of the composite thermal interface materials.

### Technical Solutions

In order to achieve the foregoing purpose of the present disclosure, the present disclosure provides a semi-solid alloy thermal interface composition, comprising: based on total atoms of 100 at. % of the semi-solid alloy thermal interface composition, 0.1-10 at. % of Bi, 20-30 at. % of In, and 65-75 at. % of Sn.

In order to achieve the foregoing purpose of the present disclosure, the present disclosure further provides a semi-solid alloy thermal interface composition, comprising: based on total atoms of 100 at. % of the semi-solid alloy thermal interface composition, 0.1-15 at. % of Bi, 5-30 at. % of In, 20-40 at. % of Ni, and 40-60 at. % of Sn.

In order to achieve the foregoing purpose of the present disclosure, the present disclosure further provides a semi-solid alloy thermal interface composition, comprising: based on total atoms of 100 at. % of the semi-solid alloy thermal interface composition, 0.1-20 at. % of Ag, 0.1-15 at. % of Bi, 10-75 at. % of In, 0.1-30 at. % of Ni, and 0.1-50 at. % of Sn.

In order to achieve the foregoing purpose of the present disclosure, the present disclosure further provides a semi-solid alloy thermal interface composition, comprising: based on total atoms of 100 at. % of the semi-solid alloy thermal interface composition, 5-15 at. % of Ag, 0.1-10 at. % of Bi, 0.1-10 at. % of Cu, 65-75 at. % of In, 0.1-10 at. % of Ni, and 0.1-10 at. % of Sn.

In order to achieve the foregoing purpose of the present disclosure, the present disclosure further provides a method for dissipating heat from an electronic component, comprising a step of: disposing the semi-solid alloy thermal interface composition as mentioned above between a heat dissipation device and the electronic component, wherein the semi-solid alloy thermal interface composition is completely solid at a room temperature, and has a liquid content of 0.1 to 70 mol % based on a total mole of 100 mol % of the semi-solid alloy thermal interface composition at a temperature of 40 to 130° C.

In one embodiment of the present disclosure, the heat dissipation device is a heat sink.

### Beneficial Effects

In use of the semi-solid alloy interface heat dissipation composition of the present disclosure in electronic components, when a temperature of the electronic components rises above 40° C., the semi-solid alloy interface heat dissipation composition begins to melt and partially becomes liquid, so as to automatically fill in the unevenness at the interface of the electronic components. Moreover, a liquid phase fraction of the semi-solid alloy thermal interface composition is less than 70% within an extreme operating temperature of the electronic components (about 130° C.), preventing significant fluid movement within the electronic components. This composition possesses both advantages of solid metals and liquid metals, and thus achieves the technical effects of easy installation, high conductivity, and low thermal contact resistance.

### DESCRIPTION OF DRAWINGS

In order to more clearly illustrate the above contents of the present disclosure, the following is a detailed description of the preferred embodiments with reference to the accompanying drawings:

FIG. 1 is a schematic structural diagram of a semi-solid alloy thermal interface composition disposed between a heat sink and a chip according to an embodiment of the present disclosure.

FIG. 2 is a schematic structural diagram of the semi-solid alloy thermal interface composition initially disposed between the heat sink and the chip according to the embodiment of the present disclosure.

FIG. 3 is a schematic structural diagram of the semi-solid alloy thermal interface composition which partially melted under operation of the chip when the semi-solid alloy thermal interface composition was disposed between the heat sink and the chip according to the embodiment of the present disclosure.

FIG. 4 is a schematic structural diagram of the semi-solid alloy thermal interface composition which further melted under the temperature of the chip continued to rise when the semi-solid alloy thermal interface composition was disposed between the heat sink and the chip according to the embodiment of the present disclosure.

FIG. 5 shows differential scanning calorimetry (DSC) analysis of a semi-solid alloy thermal interface composition according to an embodiment of the present disclosure.

FIG. 6 shows DSC analysis of a composition as a first comparative example.

FIG. 7 shows DSC analysis of a semi-solid alloy thermal interface composition according to another embodiment of the present disclosure.

FIG. 8 shows DSC analysis of a semi-solid alloy thermal interface composition according to yet another embodiment of the present disclosure.

FIG. 9 shows DSC analysis of a semi-solid alloy thermal interface composition according to yet another embodiment of the present disclosure.

FIG. 10 shows DSC analysis of a composition as a second comparative example.

### DETAILED DESCRIPTION OF PREFERRED EMBODIMENTS

In order to describe the technical solutions of the present disclosure more clearly, numerous specific details are provided in the following specific embodiments. Apparently, the present disclosure can be practiced without certain specific details.

### Ternary Semi-Solid Alloy Thermal Interface Composition:

A semi-solid alloy thermal interface composition according to a first embodiment of the present disclosure, comprises: based on total atoms of 100 at. % of the semi-solid alloy thermal interface composition, 0.1-10 at. % (e.g., 0.1, 1, 2, 3, 4, 5, 6, 7, 8, 9, or 10 at. %) of Bi, 20-30 at. % (e.g., 21, 22, 23, 24, 25, 26, 27, 28, 29, or 30 at. %) of In, and 65-75 at. % (e.g., 65, 66, 67, 68, 69, 70, 71, 72, 73, 74, or 75 at. %) of Sn.

In the present disclosure, in addition to providing the semi-solid alloy thermal interface composition containing three elements (i.e., a ternary composition) as mentioned above, according to different actual application conditions, the semi-solid alloy thermal interface compositions containing four elements (quaternary), five elements (pentanary), and six elements (senary) are respectively provided by present disclosure, shown as follows.

### Quaternary Semi-Solid Alloy Thermal Interface Composition:

In addition to bismuth, indium and tin, a semi-solid alloy thermal interface composition according to a second embodiment of the present disclosure may further comprise nickel. The semi-solid alloy thermal interface composition comprises: based on total atoms of 100 at. % of the semi-solid alloy thermal interface composition, 0.1-15 at. % (e.g., 0.1, 1, 2, 3, 4, 5, 6, 7, 8, 9, 10, 11, 12, 13, 14, or 15 at. %) of Bi, 5-30 at. % (e.g., 5, 6, 7, 8, 9, 10, 12, 14, 16, 18, 20, 22, 24, 26, 28, or 30 at. %) of In, 20-40 at. % (e.g., 20, 22, 24, 26, 28, 30, 32, 34, 36, 38, or 40 at. %) of Ni, and 40-60 at. % (e.g., 40, 42, 44, 46, 48, 50, 52, 54, 56, 58, or 60 at. %) of Sn.

### Pentanary Semi-Solid Alloy Thermal Interface Composition:

In addition to bismuth, indium, tin, and nickel, a semi-solid alloy thermal interface composition according to a third embodiment of the present disclosure may further comprise silver. The semi-solid alloy thermal interface composition comprises: based on total atoms of 100 at. % of the semi-solid alloy thermal interface composition, 0.1-20 at. % (e.g., 0.1, 1, 2, 3, 4, 5, 6, 7, 8, 9, 10, 11, 12, 13, 14, 15, 16, 17, 18, 19, or 20 at. %) of Ag, 0.1-15 at. % (e.g., 0.1, 1, 2, 3, 4, 5, 6, 7, 8, 9, 10, 11, 12, 13, 14, or 15 at. %) of Bi, 10-75 at. % (e.g., 10, 12, 14, 16, 18, 20, 22, 24, 26, 28, 30, 32, 34, 36, 38, 40, 42, 44, 46, 48, 50, 52, 54, 56, 58, 60, 62, 64, 66, 68, 70, 72, or 74 at. %) of In, 0.1-30 at. % (e.g., 0.1, 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 at. %) of Ni, and 0.1-50 at. % (e.g., 0.1, 2, 4, 6, 8, 10, 12, 14, 16, 18, 20, 22, 24, 26, 28, 30, 32, 34, 36, 38, 40, 42, 44, 46, 48, or 50 at. %) of Sn.

### Senary Semi-Solid Alloy Thermal Interface Composition:

In addition to bismuth, indium, tin, nickel, and silver, a semi-solid alloy thermal interface composition according to a fourth embodiment of the present disclosure may further comprise cooper. The semi-solid alloy thermal interface composition comprises: based on total atoms of 100 at. % of the semi-solid alloy thermal interface composition, 5-15 at. % (e.g., 5, 6, 7, 8, 9, 10, 11, 12, 13, 14, or 15 at. %) of Ag, 0.1-10 at. % (e.g., 0.1, 1, 2, 3, 4, 5, 6, 7, 8, 9, or 10 at. %) of Bi, 0.1-10 at. % (e.g., 0.1, 1, 2, 3, 4, 5, 6, 7, 8, 9, or 10 at. %) of Cu, 65-75 at. % (e.g., 60, 61, 62, 63, 64, 65, 66, 67, 68, 69, 70, 71, 72, 73, 74, or 75 at. %) of In, 0.1-10 at. % (e.g., 0.1, 1, 2, 3, 4, 5, 6, 7, 8, 9, or 10 at. %) of Ni, and 0.1-10 at. % (e.g., 0.1, 1, 2, 3, 4, 5, 6, 7, 8, 9, or 10 at. %) of Sn.

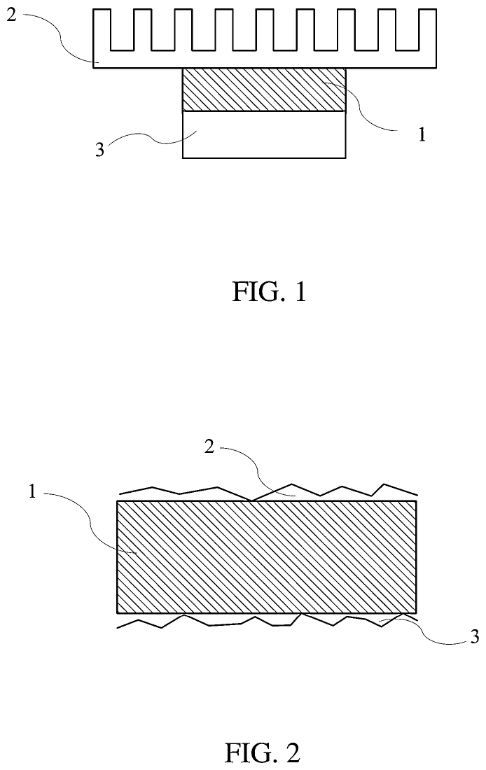

Refer to FIG. 1 to FIG. 4. A method for dissipating heat from an electronic component using the semi-solid alloy thermal interface composition as mentioned above according to a fifth embodiment of the present disclosure is provided. In the embodiment of the present disclosure, a semi-solid alloy thermal interface composition 1 is disposed between a heat dissipation device 2 and an electronic component 3. The semi-solid alloy thermal interface composition is completely solid at a room temperature, and has a liquid content of 0.1 to 70 mol % of a total mole of 100 mol % of the semi-solid alloy thermal interface composition at a temperature of 40 to 130° C.

Specifically, in the embodiment of the present disclosure, the heat dissipation device 2 is a heat sink, and the electronic component 3 is a chip. As shown in FIG. 1 and FIG. 2, the semi-solid alloy thermal interface composition 1 of the present disclosure is easily manufactured into a sheet shape based on its characteristics of being completely solid at a room temperature, so as to be easily installed between the heat dissipation device 2 and the electronic component 3.

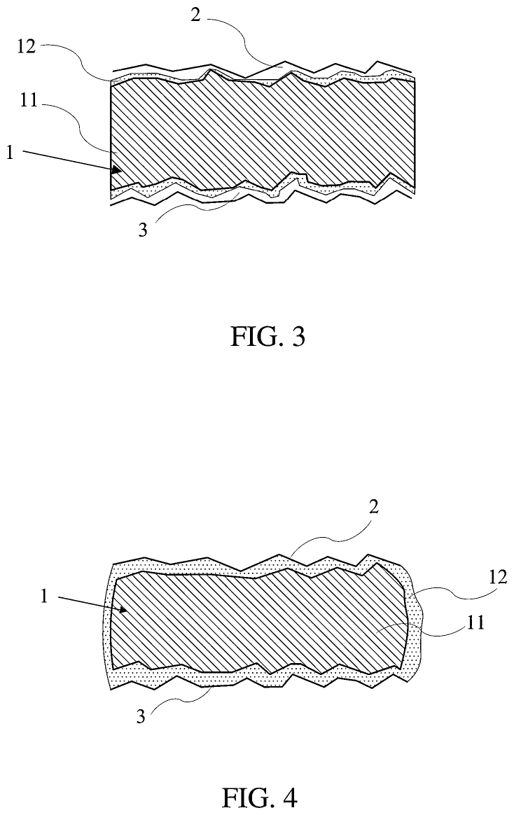

Refer to FIG. 3. When a temperature of the electronic component 3 rose above 40° C. due to a use of the electronic component 3, the semi-solid alloy thermal interface composition 1 of the present disclosure began to melt and became a mixed form in which most of the semi-solid alloy thermal interface composition 1 was solid 11, and a small part of the semi-solid alloy thermal interface composition 1 was liquid 12. As can be seen from FIG. 3, the semi-solid alloy thermal interface composition 1 closer to the electronic component 3 was liquid 12 due to a relatively high temperature in the area, so that unevenness at an interface of the electronic component 3 could be filled by the liquid 12 to improve a further heat dissipation effect for the electronic component 3.

Refer to FIG. 4. When the temperature of the electronic component 3 continued to rise, the semi-solid alloy thermal interface composition 1 melted to generate more liquid 12 to completely fill the unevenness at the interface of the electronic component 3. Moreover, a fraction of liquid phase of the semi-solid alloy thermal interface composition 1 could be controlled to be less than 70 mol % based on a total mole of 100 mol % of the semi-solid alloy thermal interface composition within an operating limit temperature of the electronic component 3 (approximately 130° C.), so that the semi-solid alloy thermal interface composition 1 would not flow significantly within the electronic component 3, and possesses both advantages of the stability of solid metals and excellent thermal conductivity of the liquid metals.

It is expected that during the life of a patent maturing from this application many relevant semi-solid alloy thermal interface composition and use thereof will be developed and the scope of this application is intended to include all such new technologies a priori.

Throughout the present application, various embodiments of the present disclosure may be presented in a range format. It should be understood that the description in range format is merely for convenience and brevity and should not be construed as an inflexible limitation on the scope of the present disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

As used herein the terms “process” and “method” refer to manners, means, techniques and procedures for accomplishing a given task including, but not limited to, those manners, means, techniques and procedures either known to, or readily developed from known manners, means, techniques and procedures by practitioners of the chemical, material, mechanical, computing, and digital fields.

Reference is now made to the following examples, which together with the above descriptions, illustrate the invention in a non-limiting fashion.

Melting points of the semi-solid alloy thermal interface compositions of the present disclosure were analyzed by differential scanning calorimetry (DSC), and compositions with the same element but different contents thereof were further analyzed.

### Experimental Method:

A target alloy to be detected was cut into pieces with a weight of about 45 to 50 mg, put into an alumina crucible, and then put into a differential scanning calorimeter to measure a melting temperature. Parameters were set to heat up from 30° C. to 150° C. (heating rate of 5° C. per minute). Then, the temperature was held for 10 minutes, followed by cooling to 30° C. (cooling rate of 5° C. per minute), and finally the temperature was held for 10 minutes. The above-mentioned heating and cooling cycles were performed a total of 3 times. The following results are presented based on average results of 2 to 3 times.

### Example 1 (the Semi-Solid Alloy Thermal Interface Composition of the Present Disclosure; the Ternary Alloy)

Refer to table 1 (Example 1) and table 2 (Comparative example 1) below. The semi-solid alloy thermal interface composition of the example 1 comprises 5 at. % of bismuth, 25 at. % of indium, and 70 at. % of tin. A composition of the comparative example 1 also comprises bismuth, indium, and tin, but with different contents, in which a content of indium is 5 at. %, while a content of tin is 90 at. %.

TABLE 1

| Bi (at. %) | In (at. %) | Sn (at. %) |
|---|---|---|
| 5 | 25 | 70 |

TABLE 2

| Bi (at. %) | In (at. %) | Sn (at. %) |
|---|---|---|
| 5 | 5 | 90 |

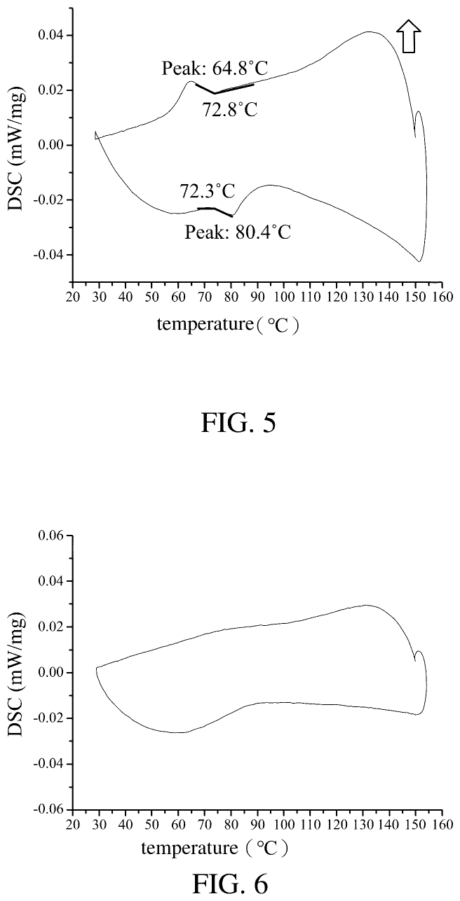

The table 3 (Example 1) and table 4 (Comparative example 1) below showed contents of melted liquid phase analyzed by PANDAT software simulation. FIG. 5 (Example 1) and FIG. 6 (Comparative example 1) showed results of DSC analysis. Table 3 showed that a content of liquid phase of the example 1 was 11.8 mol % based on a total mole of 100 mol % of the ternary alloy at 70° C., and a content of liquid phase of the example 1 was 27.6 mol % based on a total mole of 100 mol % of the ternary alloy at 120° C. An arrow in FIG. 5 indicated an exothermic direction. A conversion of solid phase into liquid phase is an endothermic reaction. Therefore, a temperature at which melting begin can be determined by observing an endothermic direction opposite to the arrow indicating the exothermic direction. Refer to a wave at the bottom in FIG. 5. A peak value was about 80.4° C., and a temperature at which melting began was about 72.3° C., indicating that the ternary alloy of the example 1 began to melt at 72.3° C. FIG. 6 did not show any peaks, indicating that the alloy of the comparative Example 1 did not melt.

TABLE 3

| | 70° C. | 120° C. |
|---|---|---|
| liquid phase | 0.118 | 0.276 |
| fraction | | |

TABLE 4

| | 70° C. | 120° C. |
|---|---|---|
| liquid phase | 0 | 0 |
| fraction | | |

### Example 2 (the Semi-Solid Alloy Thermal Interface Composition of the Present Disclosure; the Quaternary Semi-Solid Alloy)

Refer to table 5 below. The semi-solid alloy thermal interface composition of the example 2 comprises 5 at. % of bismuth, 25 at. % of indium, 25 at. % of nickel, and 45 at. % of tin.

TABLE 5

| Bi (at. %) | In (at. %) | Ni (at. %) | Sn (at. %) |
|---|---|---|---|
| 5 | 25 | 25 | 45 |

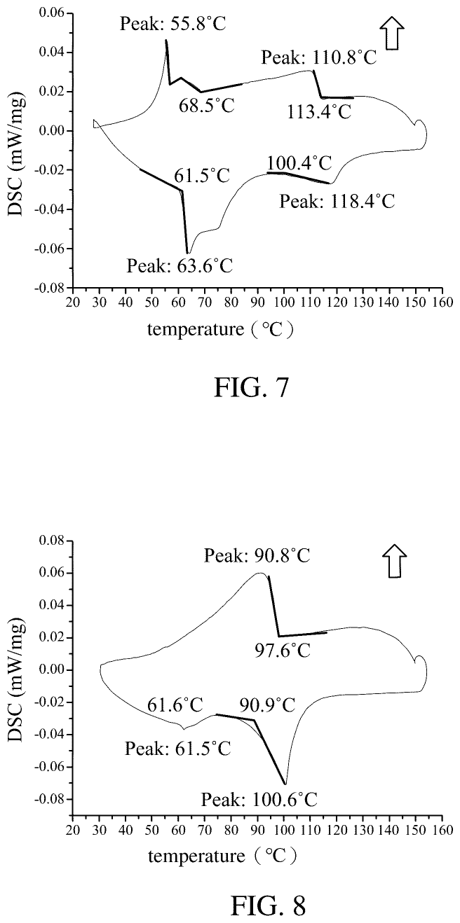

The table 6 below showed contents of melted liquid phase analyzed by PANDAT software simulation. FIG. 7 showed results of DSC analysis. Table 6 showed that a content of liquid phase of the example 2 was 20.1 mol % based on a total mole of 100 mol % of the quaternary alloy at 60° C., and a content of liquid phase of the example 2 was 41.8 mol % based on a total mole of 100 mol % of the ternary alloy at 100° C. An arrow in FIG. 7 indicated an exothermic direction. A conversion of solid phase into liquid phase is an endothermic reaction. Therefore, a temperature at which melting begin can be determined by observing an endothermic direction opposite to the arrow indicating the exothermic direction. Refer to a wave at the bottom in FIG. 7. There were two peaks, about 63.6° C. and 118.4° C. Temperatures at which melting began were about 61.5° C. and 100.4° C., indicating that two metal compounds in the quaternary alloy of the example 2 started to melt at 61.5° C. and 100.4° C. respectively.

TABLE 6

| | 60° C. | 100° C. |
|---|---|---|
| liquid phase | 0.201 | 0.418 |
| fraction | | |

### Example 3 (the Semi-Solid Alloy Thermal Interface Composition of the Present Disclosure; the Pentanary Semi-Solid Alloy)

Refer to table 7 below. The semi-solid alloy thermal interface composition of the example 3 comprises 10 at. % of silver, 5 at. % of bismuth, 50 at. % of indium, 10 at. % of nickel, and 25 at. % of tin.

TABLE 7

| Ag (at. %) | Bi (at. %) | In (at. %) | Ni (at. %) | Sn (at. %) |
|---|---|---|---|---|
| 10 | 5 | 50 | 10 | 25 |

The table 8 below showed contents of melted liquid phase analyzed by PANDAT software simulation. FIG. 7 showed results of DSC analysis (an arrow indicating an exothermic direction). Table 8 showed that a content of liquid phase of the example 3 was 18.9 mol % based on a total mole of 100 mol % of the pentanary alloy at 60° C., and a content of liquid phase of the example 3 was 47.2 mol % based on a total mole of 100 mol % of the pentanary alloy at 100° C. An arrow in FIG. 8 indicated an exothermic direction. A conversion of solid phase into liquid phase is an endothermic reaction. Therefore, a temperature at which melting begin can be determined by observing an endothermic direction opposite to the arrow indicating the exothermic direction. Refer to a wave at the bottom in FIG. 8. There were two peaks, about 61.5° C. and 100.6° C. Temperatures at which melting began were about 61.6° C. and 90.9° C., indicating that two metal compounds in the pentanary alloy of the example 3 started to melt at 61.6° C. and 90.9° C. respectively.

TABLE 8

| | 60° C. | 100° C. |
|---|---|---|
| liquid phase | 0.189 | 0.472 |
| fraction | | |

### Example 4 (the Semi-Solid Alloy Thermal Interface Composition of the Present Disclosure; the Senary Alloy)

Refer to table 9 (Example 4) and table 10 (Comparative example 2) below. The semi-solid alloy thermal interface composition of the example 4 comprises 10 at. % of silver, 5 at. % of bismuth, 5 at. % of cooper, 70 at. % of indium, 5 at. % of nickel, and 5 at. % of tin. The comparative example 2 comprises the same elements as the example 4, but contents of these elements fall outside ranges of the element contents of the semi-solid alloy thermal interface composition (the senary alloy) of the present disclosure, which are respectively 20 at. % silver, 15 at. % of bismuth, 15 at. % of copper, 20 at. % of indium, 15 at. % of nickel, and 15 at. % of tin.

TABLE 9

| Ag | Bi | Cu | In | Ni | Sn |
|---|---|---|---|---|---|
| (at. %) | (at. %) | (at. %) | (at. %) | (at. %) | (at. %) |
| 10 | 5 | 5 | 70 | 5 | 5 |

TABLE 10

| Ag | Bi | Cu | In | Ni | Sn |
|---|---|---|---|---|---|
| (at. %) | (at. %) | (at. %) | (at. %) | (at. %) | (at. %) |
| 20 | 15 | 15 | 20 | 15 | 15 |

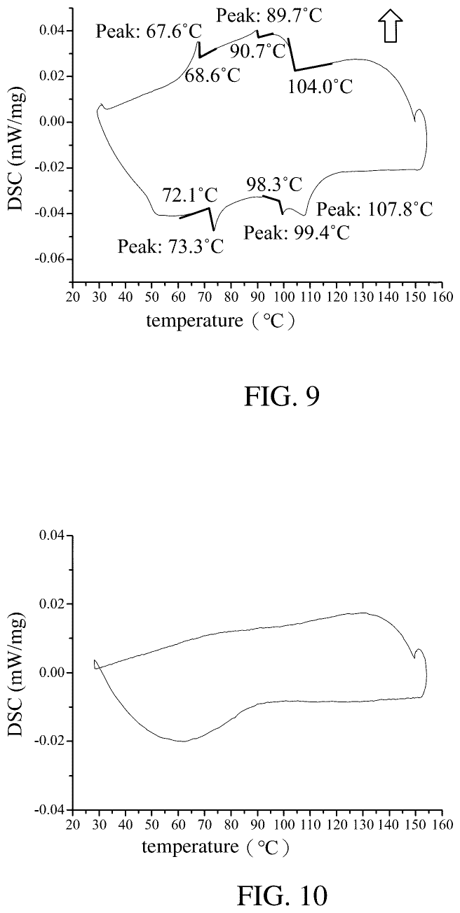

The table 11 (Example 4) and table 12 (Comparative example 2) below showed contents of melted liquid phase analyzed by PANDAT software simulation. FIG. 9 (Example 4) and FIG. 10 (Comparative example 2) showed results of DSC analysis (an arrow indicating an exothermic direction). Table 11 showed that a content of liquid phase of the example 4 was 16 mol % based on a total mole of 100 mol % of the senary alloy at 70° C., and a content of liquid phase of the example 4 was 38.7 mol % based on a total mole of 100 mol % of the senary alloy at 120° C. An arrow in FIG. 9 indicated an exothermic direction. A conversion of solid phase into liquid phase is an endothermic reaction. Therefore, a temperature at which melting begin can be determined by observing an endothermic direction opposite to the arrow indicating the exothermic direction. Refer to a wave at the bottom in FIG. 9. There were three peaks, about 73.3° C., 99.4° C., and 107.8° C. Temperatures at which melting began were about 72.1° C. and 98.3° C., indicating that multiple metal compounds in the senary alloy of the example 4 started to melt at 72.1° C. and 98.3° C. respectively. FIG. 10 did not show any peaks, indicating that the alloy of the comparative Example 2 did not melt.

TABLE 11

| | 70° C. | 120° C. |
|---|---|---|
| liquid phase | 0.160 | 0.387 |
| fraction | | |

TABLE 12

| | 70° C. | 120° C. |
|---|---|---|
| liquid phase | 0 | 0 |
| fraction | | |

As mentioned above, in use of the semi-solid alloy interface heat dissipation composition of the present disclosure in electronic components, when a temperature of the electronic components rises above 40° C., the semi-solid alloy interface heat dissipation composition begins to melt and partially becomes liquid, so as to automatically fill in the unevenness at the interface of the electronic components. Moreover, a liquid phase fraction of the semi-solid alloy thermal interface composition is less than 70 mol % based on a total mole of 100 mol % of the semi-solid alloy thermal interface composition within an extreme operating temperature of the electronic components (about 130° C.), preventing significant flow movement within the electronic components. This composition possesses both advantages of solid metals and liquid metals, and thus achieves the technical effects of easy installation, high conductivity, and low thermal contact resistance.

While the preferred embodiments of the present disclosure have been described above, it will be recognized and understood that various changes and modifications can be made, and the appended claims are intended to cover all such changes and modifications which may fall within the spirit and scope of the present disclosure.

What is claimed is:

1. A semi-solid alloy thermal interface composition, comprising: based on total atoms of 100 at. % of the semi-solid alloy thermal interface composition, 0.1-10 at. % of Bi, 20-30 at. % of In, and 65-75 at. % of Sn.

2. A semi-solid alloy thermal interface composition, comprising: based on total atoms of 100 at. % of the semi-solid alloy thermal interface composition, 0.1-15 at. % of Bi, 5-30 at. % of In, 20-40 at. % of Ni, and 40-60 at. % of Sn.

3. A semi-solid alloy thermal interface composition, comprising: based on total atoms of 100 at. % of the semi-solid alloy thermal interface composition, 0.1-20 at. % of Ag, 0.1-15 at. % of Bi, 10-75 at. % of In, 0.1-30 at. % of Ni, and 0.1-50 at. % of Sn.

4. A semi-solid alloy thermal interface composition, comprising: based on total atoms of 100 at. % of the semi-solid alloy thermal interface composition, 5-15 at. % of Ag, 0.1-10 at. % of Bi, 0.1-10 at. % of Cu, 65-75 at. % of In, 0.1-10 at. % of Ni, and 0.1-10 at. % of Sn.

5. A method for dissipating heat from an electronic component, comprising a step of:
disposing the semi-solid alloy thermal interface composition as claimed in claim 1 between a heat dissipation device and the electronic component, wherein the semi-solid alloy thermal interface composition is completely solid at a room temperature, and has a liquid content of 0.1 to 70 mol % based on a total mole of 100 mol % of the semi-solid alloy thermal interface composition at a temperature of 40 to 130° C.

6. The method for dissipating heat from the electronic component as claimed in claim 5, wherein the heat dissipation device is a heat sink.

7. A method for dissipating heat from an electronic component, comprising a step of:
disposing the semi-solid alloy thermal interface composition as claimed in claim 2 between a heat dissipation device and the electronic component, wherein the semi-solid alloy thermal interface composition is completely solid at a room temperature, and has a liquid content of 0.1 to 70 mol % based on a total mole of 100 mol % of the semi-solid alloy thermal interface composition at a temperature of 40 to 130° C.

8. The method for dissipating heat from the electronic component as claimed in claim 7, wherein the heat dissipation device is a heat sink.

9. A method for dissipating heat from an electronic component, comprising a step of:
disposing the semi-solid alloy thermal interface composition as claimed in claim 3 between a heat dissipation device and the electronic component, wherein the semi-solid alloy thermal interface composition is completely solid at a room temperature, and has a liquid content of 0.1 to 70 mol % based on a total mole of 100 mol % of the semi-solid alloy thermal interface composition at a temperature of 40 to 130° C.

10. The method for dissipating heat from the electronic component as claimed in claim 9, wherein the heat dissipation device is a heat sink.

11. A method for dissipating heat from an electronic component, comprising a step of:
disposing the semi-solid alloy thermal interface composition as claimed in claim 4 between a heat dissipation device and the electronic component, wherein the semi-solid alloy thermal interface composition is completely solid at a room temperature, and has a liquid content of 0.1 to 70 mol % based on a total mole of 100 mol % of the semi-solid alloy thermal interface composition at a temperature of 40 to 130° C.

12. The method for dissipating heat from the electronic component as claimed in claim 11, wherein the heat dissipation device is a heat sink.
